(19) United States
(12) Patent Application Publication
(10) Pub. No.: US 2009/0176430 A1
(43) Pub. Date: Jul. 9, 2009

(54) Method of making white light source by violet-LED

(76) Inventor: WadeLee Wang, Shulin City (TW)

Correspondence Address: BACON & THOMAS, PLLC, 625 SLATERS LANE, FOURTH FLOOR, ALEXANDRIA, VA, 22314-1176, US

(21) Appl. No.: 12/007,088

(22) Filed: Jan. 7, 2008

(51) Int. Cl. H01J 9/02; H01L 21/00

(52) U.S. Cl. 445/50; 438/22; 257/E21.001

(57) ABSTRACT

The present invention provides a method of making white light source by violet-LED. A phosphor powder which at least contains four elements (Zn, S, Se, O) is used with violet-LED to make white light source of LED.

The phosphor powder can be excited by violet light with wavelength from 380 to 410 nm and emits yellow light with continuous wavelength from 470 nm to 670 nm. Putting suitable amount of the phosphor powder on the surface of violet-LED chip, sealing it to be a LED, after providing a current to the LED, a white light with high color rendering index is obtained.

### FIELD OF THE INVENTION

The present invention relates to a method of making white light source by violet-LED, and more particularly to a phosphor powder of yellow light which can be excited by a violet-LED chip to generate a white light with high color rendering index.

### BACKGROUND OF THE INVENTION

In 1996, Nichia Corporation in Japan had developed a high bright blue-LED chip. The chip emits blue light and excites a phosphor powder to emit yellow light. Then the blue light and the yellow light are mixed to produce a white light with high intensity. This development make a chance for LED to replace the conventional incandescent lamp in the future to act as a white light source, and begins the era of white-LED. However, because the white light produced by the blue light and the yellow light has a low color rendering index, so it is not comportable for human eyes to see.

A white light is composed of different color lights. At least two color lights with different wavelength are required to be mixed, so as to make human eyes to feel as a white light. For example, red, blue and green lights, or blue and yellow lights, or violet and yellow lights can be mixed to make human eyes feel as a white light.

Conventional white light of three wavelengths requires three different phosphor powders in order to have high color rendering index. The three different phosphor powders must have the ability to be excited by a same light source, and the absorbing coefficients of the three phosphor powders have to be nearly the same, and the quantum effect of light energy conversion of the three different phosphor powders must be as close as possible, the proportion between the three different phosphor powders must be adjusted carefully to get an ideal white light, therefore it is very difficult to select the three different phosphor powders and to mix them perfectly.

Up to the present, it is well known by experiment that the efficiency of light energy conversion for a violet light to excite phosphor powder is higher than that of an infrared light or a blue light. Therefore white-LED with violet chip inside will become the next generation of white light source after the blue-LED of GaN.

In February 2007, SemiLEDS Co. in USA has announced an extra high intensity white light LED with 110 lumen/watt. This efficiency surpasses all kinds of known light source, thus makes a big progress for LED to enter into the lighting market. SemiLEDS also developed a high intensity violet-LED chip. The efficiency of the violet-LED chip is nearly the same as that of the blue-LED chip. Therefore, white-LED with violet chip inside will play a very important role in the future lighting market.

### SUMMARY OF THE INVENTION

The object of the present invention is to make a white light source with high color rendering index. A phosphor powder is used that can be excited by violet light (emitted from a violet-LED chip with wavelength from 380 to 410 nm) to generate a yellow light with continuous wavelength from 470 to 670 nm.

The present invention relates to a method of making white light source by a violet-LED. The violet light (wavelength 380˜410 nm) emitted by a violet-LED chip is used to excite the phosphor powder directly to generate yellow light with continuos wavelength from 470 nm to 670 nm. The yellow light is mixed with the violet light to generate a white light with high color rendering index.

The phosphor powder which emits yellow light by violet light is prepared by steps as below:

High purity (99.99% or above) ZnS powder and ZnSe powder are sunk in water with a weight proportion of 8:2 to form a mixture, and then the water is dried up; next a solid state reaction method is used to sinter the mixture on a platinum plate in a high temperature furnace (1000° C.˜1100° C.), a suitable amount (5 L/min) of air with oxygen is lead to the furnace, and then the mixture is quenched rapidly in water with room temperature to form the phosphor powder.

The violet-LED chip is a semiconductor material grown on a substrate. Putting a suitable amount of the phosphor powder on the surface of the violet-LED chip, and sealing it to be a LED, after providing a current to the LED, a white light with high color rendering index is obtained.

### BRIEF DESCRIPTION OF THE DRAWINGS

FIG. 1 shows the photoluminescence excitation spectrum of the phosphor powder according to the present invention.

FIG. 2 shows the photoluminescence emission spectrum of the phosphor powder according to the present invention.

FIG. 3 shows the photoluminescence emission spectrum of the white light LED according to the present invention.

### DETAILED DESCRIPTION OF THE PREFERRED EMBODIMENTS

The phosphor powder which emits yellow light by violet light according to the present invention is prepared by steps as below:

High purity (99.99% or above) ZnS powder and ZnSe powder are sunk in water with a weight proportion of 8:2 to form a mixture, and then the water is dried up, next a solid state reaction method is used to prepare the phosphor powder. The solid-state reaction method is to sinter the mixture on a platinum plate in a high temperature furnace (1000° C.˜1100° C.), a suitable amount (5 L/min) of air with oxygen is lead to the furnace, and then the mixture is quenched rapidly in water with room temperature to form the phosphor powder. The phosphor powder can be excited by a violet light to emit yellow light with continuos wavelength from 470 nm to 670 nm.

The phosphor powder comprises at least four elements Zn, S, Se, O.

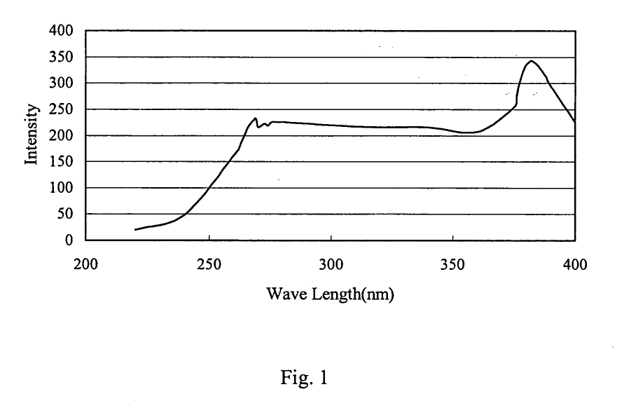

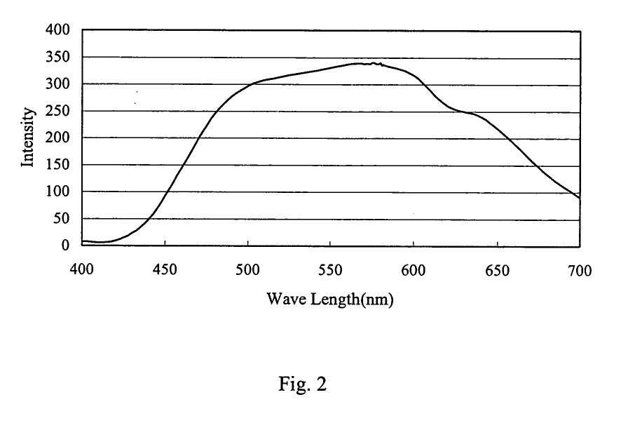

The photoluminescence excitation spectrum of the phosphor powder is shown in FIG. 1. The photoluminescence emission spectrum of the phosphor powder is shown in FIG. 2.

The violet-LED chip is a semiconductor material grown on a substrate. Putting a suitable amount of phosphor powder on surface of the violet-LED chip, and sealing it to be a LED, after providing a current to the LED, a white light with high color rendering index is obtained.

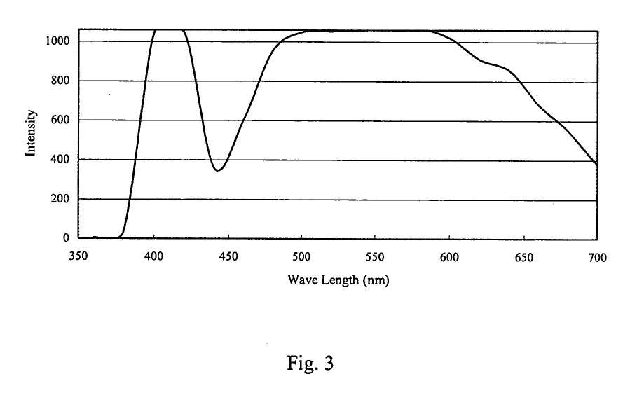

The photoluminescence emission spectrum of the white light LED is shown in FIG. 3, with chromaticity coordinate X: 0.30˜0.33 and Y: 0.29˜0.36 which is located in the range of pure white light. The color rendering index is 82˜87 with good performance.

The method of making white light source by violet-LED according to the present invention has the following features:

(1) The present invention relates to a method for making white light source with high color rendering index. A phosphor powder is used for being excited by violet light from a violet-LED chip to emit a yellow light with continuous wavelength from 470 to 670 nm. The yellow light is mixed with the violet light to generate a white light with high color rendering index. The color rendering index thereof is 82˜87, which is far beyond the color rendering index 70 of blue-LED.

(2) The white light source of the present invention is excited by violet light, so the efficiency of light energy conversion is high, thus it produces a white light with high intensity.

(3) Only one kind of phosphor powder is used to produce the white light according to the present invention, and the manufacturing process of the phosphor powder is easy to control to achieve accurate spectrum, and it also have good reproducibility. Therefore it is suitable for mass production of high quality white light source of LED.

The scope of the present invention depends upon the following claims, and is not limited by the above embodiment.

What is claimed is:

1. A method of making white light source by violet-LED, a violet light of wavelength 380 nm˜410 nm emitted from a violet-LED chip is used to excite a phosphor powder; the phosphor powder comprises at least four elements Zn, S, Se, O, and after excited by the violet light, the phosphor powder emits a yellow light with continuous wavelength from 470 nm to 670 nm, then the yellow light is mixed with the violet light to generate a white light with high color rendering index.

2. The method of making white light source by violet-LED according to claim 1, wherein the phosphor powder is prepared by steps as below: high purity (99.99% or above) ZnS powder and ZnSe powder are sunk in water with a weight proportion of 8:2 to form a mixture, and then the water is dried up; next a solid state reaction method is used to sinter the mixture on a platinum plate in a high temperature furnace (1000° C.˜1100° C.), a suitable amount of air with oxygen is lead to the furnace, and then the mixture is quenched rapidly in water with room temperature to form the phosphor powder.

3. The method of making white light source by violet-LED according to claim 1, wherein the violet-LED chip is a semiconductor material grown on a substrate.
